(19) United States
(12) Patent Application Publication
(10) Pub. No.: US 2020/0200909 A1
(43) Pub. Date: Jun. 25, 2020

(54) OPTOELECTRONIC SENSOR AND METHOD FOR OPERATING AN OPTOELECTRONIC SENSOR

(71) Applicant: Robert Bosch GmbH, Stuttgart (DE)

(72) Inventors: Norman Haag, Stuttgart (DE); Stefan Spiessberger, Weinstadt (DE)

(21) Appl. No.: 16/718,490

(22) Filed: Dec. 18, 2019

(30) Foreign Application Priority Data
Dec. 21, 2018 (DE) 10 2018 222 777.2

(51) Int. Cl. G01S 17/894; G01B 11/25; H04N 5/225; H04N 5/3745; H01S 5/183; H01S 5/40

(52) U.S. Cl. CPC G01S 17/894; G01B 11/2513; H01S 5/4025; H04N 5/3745; H01S 5/18358; H04N 5/2256

(57) ABSTRACT

An optoelectronic sensor including a laser ensemble having a plurality of individually activatable laser sources, a receiving unit and an evaluation unit, the laser ensemble being configured to address a subregion of pixels of a field of view with regard to an object through the individually activatable laser sources with the aid of a sequence of distinguishable illumination patterns, and the receiving unit is configured to receive reflections and/or dispersions of these illumination patterns, and the evaluation unit is configured to carry out complete object imaging as a function of received illumination patterns of the subregion of the field of view.

### FIELD OF THE INVENTION

The present invention relates to an optoelectronic sensor, in particular a LIDAR sensor, and to a method for operating an optoelectronic sensor.

### BACKGROUND INFORMATION

There are believed to be two basic approaches for operating LIDAR systems. For one, there are believed to be flash systems in which the entire scene or the entire field of view of the system is illuminated and a parallel detection then takes place. For another, there are believed to be scanner systems in which the scene or the field of view is scanned by a single laser beam.

Regular flash systems include two-dimensional detectors, which record a full image of the scene runtime in encoded form. An alternative concept for the detection is what is known as ‘compressed sensing’ (CS) LIDAR, which is also known by the term ‘photon-counting LIDAR’.

Semiconductor lasers (VCSEL) configured as surface emitters are easily able to be controlled individually. For example, an addressable VCSEL array is made up of 8×32 emitters. In addition, such a VCSEL array could be scaled to a larger emitter number. In combination with a downstream imaging optics, the laser beams of the emitters are able to be imaged in the distance.

In such a context, patent document DE 10 2007 004609 A1 discusses a VCSEL array laser scanner in which laser emitters can be activated one after the other.

In the context of a LIDAR system, patent document DE 20 2013 012622 U1 discusses the principle of an addressable illumination of a field of view, a light modulator, in particular a spatial light modulator (SLM), being described there. However, it has the disadvantage that a field of view can be scanned only very slowly when using an SLM.

For flash-based systems, corresponding 2D detectors are required, which are very expensive on account of the high electronic demands (e.g., a high read-out time in the range of μs and high sensitivity). The low efficiency of these detectors limits the range or requires a very high output of the light source.

The compressed-sensing approach, on the other hand, uses relatively cost-effective components that are suitable for the mass market, and it is possible to dispense with a complex imaging optics. In addition, because of the missing imaging optics, the approach does not suffer from imaging errors. However, it has the disadvantage that a relatively large number of individual images is required in order to reconstruct a scene. In addition, the conventional technical implementations of a compressed-sensing approach are susceptible to spatial fluctuations of the light source.

A compressed-sensing system includes three components. A first component is a light source while a second component represents an element for structuring light. The third component is a 1D detector. Commercially available digital light modulators (DLMs) are normally utilized for structuring the light. In a typical variant of a CS system, this DLM is connected downstream from the light source, and the scene is illuminated in a structured manner. The backscattered light is subsequently recorded using a collective lens and measured by a 1D photodetector. The photodetectors are usually avalanche photodiodes (APDs), which allow for high sensitivity at a rapid measuring time. However, in this case it is necessary to illuminate a scene using a complete structuring set. In addition, the illumination pattern is disadvantageously emitted on the transmitter side via a digital micromirror device (DMD), in which case 50% of the light output is usually lost because of the suppression of individual pixels, since 50% of the patterns are typically made up of dark pixels.

### SUMMARY OF THE INVENTION

According to a first aspect, the present invention relates to an optoelectronic sensor which, for instance, may be installed on a vehicle. An optoelectronic sensor may particularly include a LIDAR sensor or some other laser-operated sensor. The optoelectronic sensor according to the present invention includes a laser ensemble having a plurality of individually activatable laser sources. Such a ‘laser ensemble’ may especially include a VCSEL array. The laser ensemble according to the present invention has a plurality of individually activatable laser sources, and it is possible to generate various patterns within the laser ensemble based on an activation of the plurality of individually activatable laser sources. In other words, the laser sources are able to be addressed individually and/or in any desired combination for the emission of laser beams. Moreover, the optoelectronic sensor according to the present invention includes a receiving unit, in particular a LIDAR detector, as well as an evaluation unit, in particular a CPU and/or a microcontroller and/or an electronic control unit and/or a graphics processor. Because of the individually activatable or addressable laser sources using a sequence, in particular a time sequence, of different illumination patterns per illumination pattern, the laser ensemble is able to address a subregion of pixels of a field of view that is allocated to the optoelectronic sensor with regard to an object to be measured. The illumination patterns are reflected at the corresponding locations of the object and/or dispersed and received by a receiving unit and allocated to the field of view. In other words, per illumination pattern, a portion of the total number of pixels of a field of view is addressed. Because of the emitting of distinguishable illumination patterns according to the present invention, a fraction (such as 5% to 50%) of the measurements that would theoretically be required in order to individually address each pixel of the field of view may be carried out in order to obtain a sufficient image of the object. The receiving unit may particularly supply the detected illumination patterns to the evaluation unit. With the aid of the evaluation unit, complete object imaging is able to be carried out with regard to the subregion of the field of view as a function of the received illumination pattern. In other words, an extrapolation of the recordings that are associated with the addressed subregion of pixels of the field of view is performed in order to prepare a complete image. In still other words, the optoelectronic sensor according to the present invention is able to be operated by a compressed sensing method, for instance, while laser sources of a laser ensemble are individually addressable and/or activatable in order to generate the illumination patterns that are required for the compressed sensing method. In a compressed sensing method, in particular a scene to be ascertained is illuminated using a plurality of different spatial illumination patterns. The illumination patterns in such an illumination may be orthogonal. Based on this plurality of measurements, and in particular because of the orthogonality of the patterns, it is possible to reconstruct the scene by multiplying the measured values of the respective patterns by the associated patterns and summing them up, which corresponds to a linear combination of an orthonormal base, for example.

The optoelectronic sensor according to the present invention thus allows for a generation of a rapid sequence of illumination patterns, which exceeds the illumination speed of a conventional DMD-based compressed sensing method many times over. Moreover, the individual illumination patterns and their time characteristic are freely selectable because of the laser ensemble. In addition, better eye safety is achieved through an optimization of this illumination pattern sequence, and higher transmission outputs are possible in the process. Better sensor statistics and a better sensor range are therefore also able to be realized according to the present invention. In addition, the optoelectronic sensor according to the present invention has the advantage that the power loss is clearly reduced in comparison to previously described conventional compressed sensing systems because in essence all emitted photons are used for the object detection, whereas photons in known compressed sensing methods are absorbed in order to generate the pattern. A greater measure of transmission power is therefore able to be used with the aid of the optoelectronic sensor according to the present invention.

The further descriptions herein show further developments of the present invention.

According to one advantageous further development of the optoelectronic sensor according to the present invention, it is possible to sufficiently image the addressed field of view using a subset of 5% to 50%, in particular 20% to 30% (usually approximately 25%) of the patterns required for a complete reconstruction if an individual measurement were carried out for each pixel of the field of view. For instance, in this case each measurement carried out according to the present invention has a pattern that is distinguishable from the other measurements. In other words, a percentage ratio of a number of distinguishable illumination patterns of the sequence to a theoretical number of measurements that would be required in order to address each pixel of a field of view individually amounts to 5% to 50%. Much less data resulting from the received illumination patterns are therefore required in order to generate complete object imaging than in conventional (flash) systems. An undershooting of 5% of the addressed partial patterns may have a disadvantageous effect on the accuracy of the object detection.

According to a further advantageous development of the optoelectronic sensor according to the present invention, the receiving unit has a one-dimensional detector. This may particularly, but not necessarily, be an avalanche photodiode (APD). In an advantageous manner, the method of operation of the optoelectronic sensor according to the present invention thus allows for the use of cost-effective detectors.

According to one further advantageous development of the optoelectronic sensor according to the present invention, at least one laser source of the plurality of laser sources has a rectangular form. In particular, also half or the totality of the laser sources may have a rectangular form.

In particular, the distinguishable illumination patterns of the measurement according to the present invention are such that no gaps remain in the addressed field of view after a measurement has been completed. In other words, because of the sequence of distinguishable illumination patterns, each pixel of the field of view is addressable at least once.

According to an advantageous further development of the present invention, the laser ensemble according to the present invention may include a VCSEL array and/or a plurality of edge emitters. In addition, any semiconductor laser known to one skilled in the art is able to be used for the laser ensemble.

According to an advantageous further development, the distinguishable illumination patterns are able to be generated by the evaluation unit with the aid of a Hadamard matrix and/or with the aid of a Walsh matrix. These matrices have the particular advantage that they form a completely orthogonal base and thus allow for complete object imaging as a function of the received illumination patterns.

According to another advantageous further development of the optoelectronic sensor according to the present invention, the laser ensemble may include an optical imaging unit, which is configured to guide the illumination patterns onto the object under an emission angle predefined by the position of the imaging unit. In this way, exact imaging of the illumination patterns that stem from the individually activated laser sources of the laser ensembles onto the object is able to be realized. In particular, the optical imaging unit may include a micro-lens system and an objective such as a projection lens. According to the micro lens system and the objective, a broadening or a reduction in size or a collimation of the beam emitted onto an object is able to be generated.

The following aspect of the present invention accordingly features the advantageous embodiments and further developments having the aforementioned features as well as the general advantages of the optoelectronic sensor according to the present invention. A renewed enumeration is therefore dispensed with in order to avoid repetitions.

According to a second aspect, the present invention relates to a method for operating the optoelectronic sensor according to the first invention aspect. The method is a compressed sensing method, in particular. The method according to the present invention includes the steps of emitting a sequence of distinguishable illumination patterns using an afore-described laser ensemble in order to address the pixels of a field of view with regard to an object, the illumination patterns addressing a subregion of the pixels of the field of view in each case. In response, corresponding reflected and/or back-scattered illumination patterns are received, which are backscattered and/or reflected by the object. Depending on the addressed subregions of the field of view or depending on the received corresponding reflected and/or dispersed illumination patterns, complete object imaging is carried out in the evaluation unit, for example.

In particular, the distinguishable illumination patterns are orthogonal with respect to one another. This makes it possible to perform an energy-efficient measurement, i.e. a measurement that saves laser power and is time-efficient.

In the following text, exemplary embodiments of the present invention are described in detail with reference to the accompanying drawings.

### BRIEF DESCRIPTION OF THE DRAWINGS

FIG. 1 shows a flow diagram of a variant of the method according to the present invention.

FIG. 2 shows an illustration of a sequence of illumination patterns according to the present invention.

FIG. 3 shows a variant of a transmission unit of an optoelectronic sensor according to the present invention.

FIG. 4 shows a variant of a laser ensemble of an optoelectronic sensor according to the present invention.

FIG. 5 shows a variant of an optoelectronic sensor according to the present invention.

### DETAILED DESCRIPTION

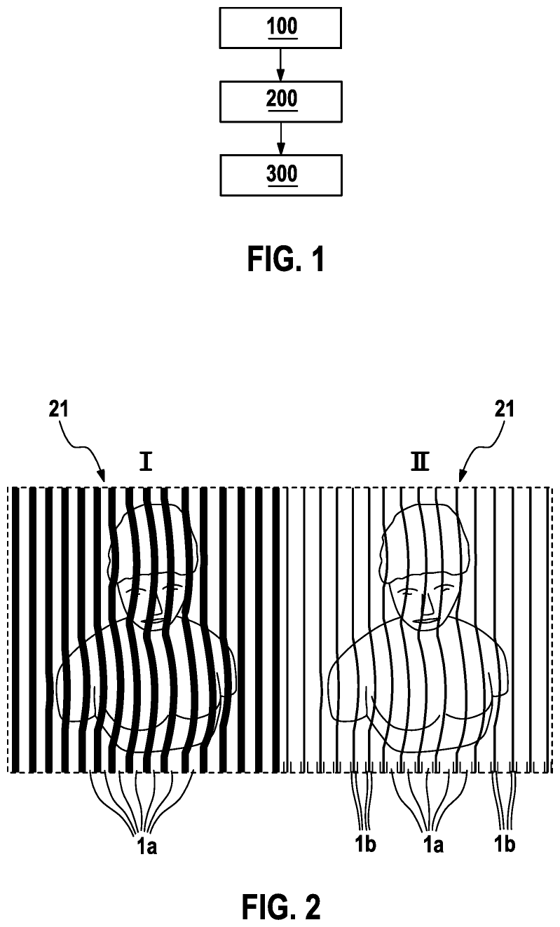

FIG. 1 shows a flow diagram of a variant of the method according to the present invention. In a first step 100, a sequence of distinguishable illumination patterns 1a, 1b is emitted with the aid of a laser ensemble 2, which includes a plurality of individually addressable or activatable laser sources 3a through 3j. Through the emitting according to first step 100, in particular a subregion of pixels of a field of view is addressed per illumination pattern, the field of view being associated with an object 21. Especially three distinguishable illumination patterns are emitted, which address all of the pixels of the field of view at least once. In a second step 200, reflected or dispersed illumination patterns that correspond to emitted illumination patterns 1a, 1b are received, for instance with the aid of a receiving unit 11. In a third step 300, the completing of the field of view with regard to object imaging takes place. In other words, an image is generated from an addressing of pixels of 25% of the pixels of the field of view as a function of the addressed subregion of the field of view. This may be done with the aid of an evaluation unit 7 such as a graphics processor, for instance.

FIG. 2 shows an object 21 in the form of a bust. This object 21 is illuminated in a first figure part I by a first illumination pattern 1a. In a second Figure part II, object 21 is illuminated by a second illumination pattern 1b, the black bands, which were not detected by first illumination pattern 1a, being covered by second illumination pattern 1b, with the exception of a reduced black band that represents a non-addressed subregion of the field of view. In particular, a superposition of first illumination pattern 1a and second illumination pattern 1b is shown in Figure part II of FIG. 2 in order to illustrate the composition of illumination patterns 1a, 1b, based on which an object imaging is completed. More specifically, non-addressed pixels are shown by black bands in the illumination patterns 1a, 1b in FIG. 2, II. However, a complete image of the object is able to be generated based on an image as shown in Figure part II.

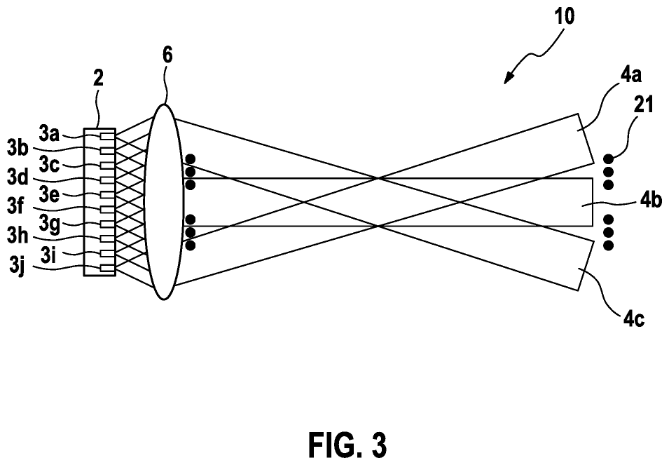

FIG. 3 shows a variant of a transmission unit 10 of a component assembly 40 according to the present invention. Transmission unit 10 has a laser ensemble 2 which includes a plurality of individually addressable and activatable laser sources 3a through 3j. Via the individually addressable laser sources 3a through 3j and an objective 6, any desired illumination pattern including first through third light beams 4a to 4c is able to be projected onto an object in order to receive, through the afore-described reflection of these light beams 4a through 4c, a series of patterns from which an image of an object 21 is able to be completed.

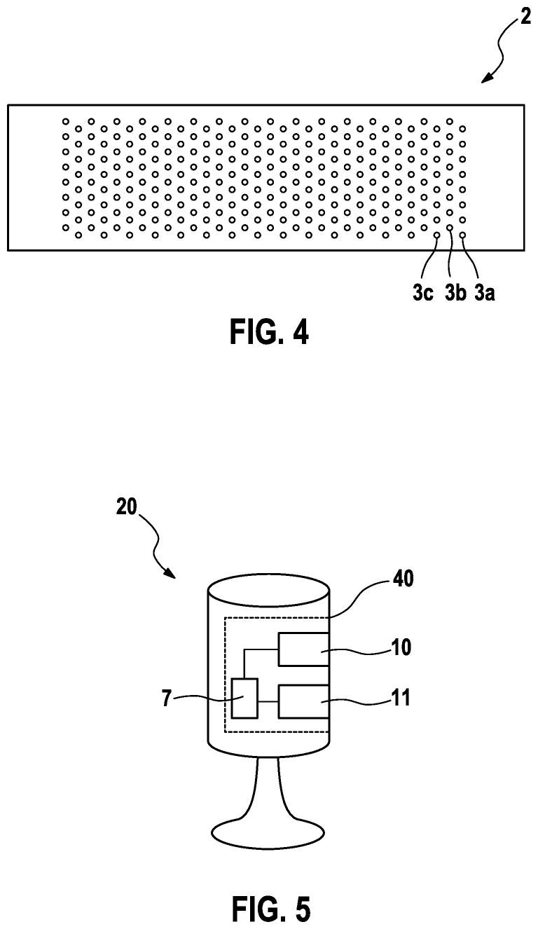

FIG. 4 shows a variant of a laser ensemble 2 of a component assembly 40 that has a plurality of laser sources 3a through 3c. In addition to first through third laser sources 3a through 3c, all other points of laser ensemble 2 illustrated in FIG. 4 —laser ensemble 2 being a VCSEL array in this instance —, are individually addressable in any desired manner in order to generate desired illumination pattern 1a, 1b.

FIG. 5 shows a LIDAR sensor 20 according to the present invention. LIDAR sensor 20 includes a transmission unit 10 as well as a receiving unit 11. In addition, an evaluation unit 7 is provided, which is connected to receiving unit 11 and transmission unit 10. Evaluation unit 7 particularly makes it possible to generate illumination patterns 1a, 1b and to complete received illumination patterns 1a, 1b, which were reflected or dispersed with regard to a field of view, in order to form an object image.

1-10. (canceled)

11. An optoelectronic sensor, comprising:
a laser ensemble having a plurality of individually activatable laser sources;
a receiving unit; and
an evaluation unit;
wherein the laser ensemble is configured to address a subregion of pixels of a field of view with regard to an object through the individually activatable laser sources with a sequence of distinguishable illumination patterns per distinguishable illumination pattern, and the receiving unit is configured to receive reflections and/or dispersions of these distinguishable illumination patterns, and the evaluation unit is configured to carry out complete object imaging as a function of received illumination patterns, which address the subregion of pixels of the field of view.

12. The optoelectronic sensor of claim 11, wherein a percentage ratio of a number of distinguishable illumination patterns in the sequence to a number of measurements required to address each pixel of the field of view individually amounts to 5% to 50%.

13. The optoelectronic sensor of claim 11, wherein each pixel of the field of view is addressable at least once because of the sequence of distinguishable illumination patterns.

14. The optoelectronic sensor of claim 11, wherein the receiving unit includes a one-dimensional detector.

15. The optoelectronic sensor of claim 11, wherein at least one surface of a laser source of the plurality of laser sources from which a laser beam is emittable has a rectangular form.

16. The optoelectronic sensor of claim 11, wherein the laser ensemble includes a VCSEL array and/or a plurality of edge emitters.

17. The optoelectronic sensor of claim 11, wherein the distinguishable illumination patterns are generatable by a Hadamard matrix and/or a Walsh matrix.

18. The optoelectronic sensor of claim 11, wherein an optical imaging unit is connected downstream from the laser ensemble, the optical imaging unit being configured to guide the illumination patterns onto the object under an emission angle predefined by the position of the imaging unit.

19. A method for operating an optoelectronic sensor, the method comprising:
emitting a sequence of distinguishable illumination patterns using a laser ensemble having a plurality of individually activatable laser sources to address pixels of a field of view, a subregion of the pixels of the field of view being addressed per illumination pattern;
receiving, in response thereto, corresponding reflections and/or dispersed illumination patterns; and
carrying out complete object imaging as a function of the received corresponding reflected and/or dispersed illumination patterns;
wherein the optoelectronic sensor includes:
the laser ensemble having the plurality of individually activatable laser sources;
a receiving unit; and
an evaluation unit;
wherein the laser ensemble is configured to address the subregion of pixels of the field of view with regard to an object through the individually activatable laser sources with a sequence of distinguishable illumination patterns per distinguishable illumination pattern, wherein the receiving unit is configured to receive the reflections and/or the dispersions of the distinguishable illumination patterns, and wherein the evaluation unit is configured to carry out the complete object imaging as the function of received illumination patterns, which address the subregion of pixels of the field of view.

20. The method of claim 19, wherein the distinguishable illumination patterns are orthogonal to one another.
